(19) United States
(12) Patent Application Publication
(10) Pub. No.: US 2026/0088780 A1
(43) Pub. Date: Mar. 26, 2026

(54) ADAPTIVE BIAS CONTROL OF CASCODE DRIVERS IN ENVELOPE TRACKING POWER AMPLIFIER DEVICES, SYSTEMS, AND METHODS

(71) Applicant: pSemi Corporation, San Diego, CA (US)

(72) Inventors: James Francis McElwee, Austin, TX (US); Yuan Wei, Arlington Heights, IL (US)

(21) Appl. No.: 18/898,356

(22) Filed: Sep. 26, 2024

(51) Int. Cl. H03F 3/24; H03F 1/02; H03F 1/22; H03F 3/26; H03F 3/45

(52) U.S. Cl. CPC H03F 3/245; H03F 1/0222; H03F 1/223; H03F 3/265; H03F 3/45183; H03F 2200/102; H03F 2200/451

(57) ABSTRACT

Embodiments of the present disclosure include adaptive bias control of cascode drivers in envelope tracking power amplifier devices, systems, and methods. In some aspects, a wireless communication device is disclosed that includes a power amplifier. The power amplifier may include a driver stage configured to receive a variable voltage supply signal, and a power amplifier stage following the driver stage. In some embodiments, the driver stage includes a cascode gate bias circuit configured to receive a first signal that is based on the variable voltage supply signal; and a cascode amplifier stage comprising a first field effect transistor (FET) and a second FET in a stacked configuration. The cascode gate bias circuit may be further configured to adaptively convert the first signal into a bias signal for a gate of the first FET. The power amplifier stage may be configured to generate an amplified signal based on the intermediate output.

### BACKGROUND

This disclosure relates to electronic radio frequency (RF) circuits, and more particularly to envelope tracking power amplifier methods, systems, and devices.

The use of envelope tracking is a common way to modulate the voltage supply of a power amplifier in RF applications, such as wireless communications using third generation (3G) through fifth generation (5G) technologies. In these and other applications, it is desirable that a gain of the power amplifier remain relatively constant over an operating range of the voltage supply. Gain dispersion is a measure of the variation in gain over an operating range of the voltage supply, and it may be desirable for gain dispersion to reflect that the gain exhibits variation that remains within specified bounds over a range of supply voltage.

Power amplifiers fabricated from certain materials and/or using certain methods, such as Gallium Arsenide (GaAs) heterojunction bipolar transistors (HBTs), are known to have satisfactory gain dispersion in many applications of interest. However, such power amplifiers have a drawback that they may be overly expensive for a given application when measured in cost per unit area. Using lower-cost materials and techniques for fabrication, such as the use of silicon-on-insulator (SOI) laterally double-diffused metal-oxide semiconductor (LDMOS) technologies, can save on cost while beneficially adding functionality and features compared to higher-cost materials and fabrication techniques, but there are drawbacks, particularly when paired with cascode-type driver or gain stages.

Cascode-type gain stages can have certain benefits over common-source-type gain stages. Among the benefits are greater unilateral stability by reducing the impact of transistor capacitance, such as capacitance between gate and drain (Cgd or Miller capacitance), leading to higher bandwidth and improved stability. However, cascode-type gain stages can have poor gain dispersion, particularly when paired with constant cascode gate voltage control.

In order to reap the benefits of gain stages in a power amplifier that use lower cost materials and fabrication techniques, new solutions and circuits are needed to maintain gain dispersion in a desirable range.

### SUMMARY

Embodiments of the present disclosure include adaptive bias control of cascode drivers in envelope tracking power amplifier devices, systems, and methods.

In some aspects, a radio frequency (RF) circuit is disclosed. In some embodiments, the RF circuit includes a driver stage to receive a variable voltage supply signal. In some embodiments, the driver stage includes a cascode gate bias circuit configured to receive the variable voltage supply signal; and a cascode amplifier stage comprising a first field effect transistor (FET) and a second FET in a stacked configuration. In some embodiments, the cascode gate bias circuit is configured to adaptively convert the variable voltage supply signal into a bias signal for a gate of the first FET, and the cascode amplifier stage is configured to receive a radio frequency input signal at a gate of the second FET and to produce an intermediate output at a drain of the first FET.

In some aspects, a wireless communication device is disclosed. In some embodiments, the wireless communication device includes a power amplifier. In some embodiments, the power amplifier includes a driver stage configured to receive a variable voltage supply signal, and a power amplifier stage following the driver stage. In some embodiments, the driver stage includes a cascode gate bias circuit configured to receive a first signal that is based on the variable voltage supply signal; and a cascode amplifier stage comprising a first field effect transistor (FET) and a second FET in a stacked configuration. In some embodiments, the cascode gate bias circuit is further configured to adaptively convert the first signal into a bias signal for a gate of the first FET, and the cascode amplifier stage is configured to receive a radio frequency input signal at a gate of the second FET and to produce an intermediate output at the drain of the first FET. In some embodiments, the power amplifier stage is configured to generate an amplified signal based on the intermediate output.

In some aspects, a method of operating a wireless communication device is disclosed. In some embodiments, wireless communication device includes a cascode gate bias circuit; and a cascode amplifier stage comprising a first FET and a second FET in a stacked configuration. In some embodiments, the method includes receiving, by the cascode gate bias circuit, a variable voltage supply signal; adaptively generating, by the cascode gate bias circuit, a bias signal based on the variable voltage supply signal to lower a gain dispersion of a power amplifier comprising the driver stage and a power amplifier stage; receiving, at gate of the first FET, the bias signal; receiving, at the gate of the second FET, a radio frequency input signal; and generating a first output signal at the drain of the first FET

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1 illustrates an example of a power amplifier, in accordance with one or more embodiments of the present disclosure.

FIG. 2 illustrates an example driver stage, in accordance with one or more embodiments of the present disclosure.

FIG. 3 illustrates an example bias circuit, in accordance with one or more embodiments of the present disclosure.

FIG. 4 illustrates another example of a bias circuit, in accordance with one or more embodiments of the present disclosure.

FIG. 5 illustrates an example embodiment of a differential amplifier of a bias circuit, in accordance with one or more embodiments of the present disclosure.

FIG. 6 illustrates an architecture of a wireless communication device, in accordance with one or more embodiments of the present disclosure.

FIG. 7 is a method of operating a wireless communication device, in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of RF power amplifier circuits. It will be appreciated that various improvements disclosed herein encompass innovative circuits, hardware components, architectures, and related logic that are applicable to applications beyond RF power amplifier circuits.

As one with skill in the art may appreciate, the terminals of a given amplifying transistor are designated in accordance with the type of transistor being implemented. For example, a field-effect transistor (FET) includes a gate terminal, a drain terminal, and a source terminal. The term “bias” is often used to describe varying voltage or current at a gate terminal an amplifying FET transistor.

As used herein the terms “supply” and “bias” are distinct. In some contexts, the term “bias” is used to refer to an input condition, for example, varying voltage or current at either a gate terminal or a base terminal of an amplifying transistor. In these two examples base current bias or gate voltage bias set the quiescent collector current or quiescent drain current, respectively. Regardless of transistor type or terminal name, the term “bias” is used to refer to an input condition impacting efficiency, linearity, or other performance aspects of the amplifying transistor. In some contexts, the term “supply” is used to refer to the voltage applied to (and current sourced to) the output side of an amplifying transistor. For example, in the case of a FET in common-source configuration, the supply may be applied to the drain terminal. In another example, in the case of a BJT in common-emitter configuration, the supply may be applied to the collector terminal. In some contexts, the term “supply voltage” refers to the voltage applied at the output side of an amplifying transistor (i.e. drain or collector terminals depending on transistor type). One with skill in the art may appreciate, while these terms may vary across transistor types the enclosed methods and techniques are contemplated to be used across all transistor types.

Power amplifier systems, methods, and devices are presented herein that provide envelope tracking power amplification with low gain dispersion at reasonable cost. In some embodiments, a “hybrid” power amplifier design is employed in which a driver stage is followed by a power amplifier stage, and in which the driver stage is fabricated using one type of device and the power amplifier stage is fabricated using another type of device. For example, the driver stage may include SOI/LDMOS devices, and the power amplifier stage may include GaAs HBT devices. A SOI/LDMOS driver in such a power amplifier may provide a number of benefits, including: improved programmability; improved integration (e.g., with Mobile Industry Processor Interface (MIPI), Power Amplifier Controller (PACs), etc.); access to SOI/LDMOS switches (e.g., switchable RF path options, such as switchable paths between wireless cellular 2G and 5G final power amplifier stages); potential overall cost reduction; and/or bottom-side mount options for the driver stage(s), as compared to GaAs drivers which may not be mounted on the bottom side. However, a SOI/LDMOS driver can have an unsatisfactory gain dispersion under typical operating conditions in which supply voltage is varying with RF signal envelope. Although GaAs HBT drivers can have good gain dispersion, such drivers do not yield many of the benefits listed above for SOI/LDMOS drivers. This disclosure provides solutions to enable the use of SOI/LDMOS drivers with satisfactory gain dispersion.

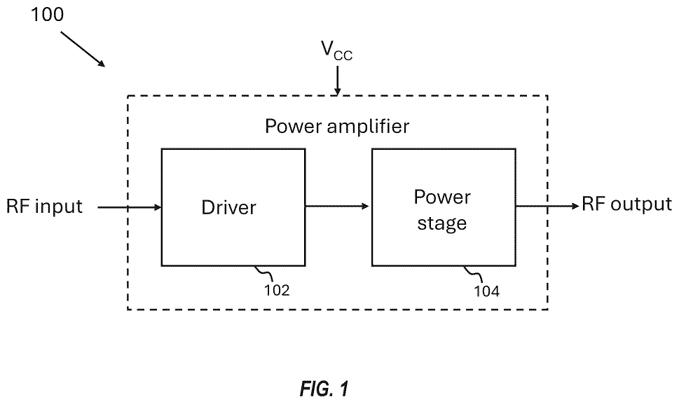

This disclosure recognizes that it is desirable to control a gate bias voltage of a cascode amplifier stage over a range of the variable voltage supply signal during envelope tracking operation. This feature is further explained with respect to FIG. 1. FIG. 1 illustrates an example of a power amplifier 100, in accordance with one or more embodiments of the present disclosure. The power amplifier 100 includes a driver stage 102 connected to a power stage 104 as shown. The power stage 104 may also be referred to as a power amplifier stage 104. The power amplifier 100 is configured to receive an RF signal (RF input) and amplify the RF signal to produce an RF output, which has a greater power than the RF input. The power amplifier 100 may be used in an application in which the voltage supply signal V_{CC} is varying. For example, in a wireless communication application that uses envelope tracking, the voltage supply signal V_{CC} may be a variable voltage supply signal that varies according to the envelope of the RF input signal. The driver stage 102 may include a SOI/LDMOS driver, and the power stage 104 may include a GaAs HBT power amplifier stage, thereby forming a “hybrid” power amplifier 100 designed to combine benefits of using a SOI/LDMOS driver with a GaAs power amplifier stage, while minimizing the drawbacks.

In some embodiments, the driver stage 102 may further include a switch (not shown) at the driver 102 output that switchably sends the RF signal to an amplifier designed for the cellular signal of interest. For example, the power stage 104 may include one power amplifier designed for RF operating frequencies and bandwidths associated with 2G signals and another power amplifier designed for RF operating frequencies and bandwidths associated with 5G signals, with 2G signals routed to the 2G amplifier and 5G signals routed to the 5G amplifier. Such embodiments are within the scope of this disclosure.

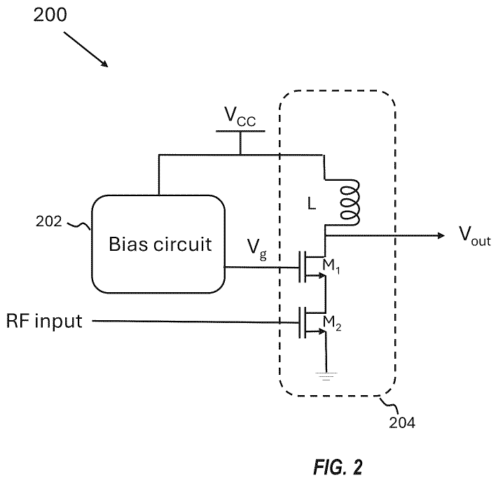

FIG. 2 illustrates an example driver stage 200, in accordance with one or more embodiments of the present disclosure. In some embodiments, the driver stage 200 may be a more detailed diagram of the driver stage 102 of FIG. 1, with Vₒᵤₜ provided as an input to the power amplifier stage 104. As shown, the driver stage 200 includes a bias circuit 202 and a cascode amplifier stage 204. The cascode amplifier stage 204 includes a common gate MOS transistor M₁ (e.g., a MOS field effect transistor or MOSFET) and a common source MOS transistor M₂ (e.g., a MOSFET) configured in a stacked configuration, with an inductor L connected between M₁ and a variable voltage supply signal V_{CC}. In some embodiments, the source of M₁ is connected to the drain of M₂. In some embodiments, the bias circuit 202 receives the variable voltage supply signal V_{CC} as an input and generates a gate voltage bias signal V_{g} as an output. (Thus, the bias circuit 202 may also be referred to as a cascode gate bias circuit.) The gate voltage bias signal V_{g} is used to bias the gate voltage of common gate transistor M₁. An RF input, such as a signal for wireless communication, is received and provided as the gate voltage of common source transistor M₂.

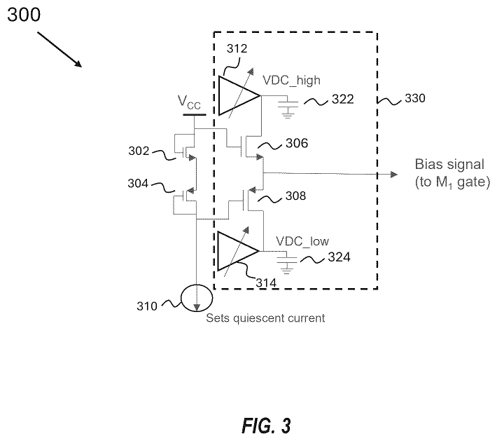

This disclosure recognizes that it is desirable for the bias circuit 202 to generate a bias signal V_{g} that tracks V_{CC} such that gain dispersion remains in an acceptable range, even with RF input signals having bandwidths greater than 100 megahertz (MHz), which may occur in cellular wireless applications, such as when certain 4G or 5G cellular bands are used. For example, one band of interest is Band 41 in 4G/Long Term Evolution (LTE) systems. More generally, bandwidth of the RF signal depends on the band and carrier configuration chosen for communication and may be less than 100 MHz in some applications and scenarios. Example bias circuits that yield desirable gain dispersions for such signals described above are presented in FIGS. 3-5 and discussed further below.

FIG. 3 illustrates an example bias circuit 300, in accordance with one or more embodiments of the present disclosure. In this embodiment, bias circuit 300 includes a first push-pull buffer stage 330 that includes a pull-up FET 306, a pull-down FET 308, a first DC voltage source 312, a second DC voltage source 314, and capacitors 322, 324. As shown, the first DC voltage source 312 is connected to the drain of the pull-up FET 306, and the second DC voltage source 314 is connected to the drain of the pull-down FET 308. In some embodiments, the first DC voltage source 312 and the second DC voltage source 314 may receive an input voltage V_{REF} from a bias generator and/or V_{BAT}. A bias signal (signal labeled as “Bias signal (to M₁ gate)”) is generated between the pull-up FET 306 and the pull-down FET 308 as shown. The DC voltage sources 312, 314 may be sued used to set clipping voltages of the bias circuit 300 relative to the variable voltage signal V_{CC}. For example, as V_{CC} increases, voltage source 312 may be set to clip the output from going above VDC_high. As V_{CC} decreases, the voltage source 314 may be set to clip the output from going below VDC_low (which is less than VDC_high). Each of the FETs 302, 304, 306, and 308 may be implemented as SOI and/or LDMOS devices.

The bias circuit 300 further includes a second buffer stage that includes a first FET 302 that is diode-connected, a second FET 304 that is diode-connected, and a current source 310. The sizes of the first FET 302 and second FET 304 are ratioed or matched in a desired manner with pull-up FET 306 and pull-down FET 308, respectively. In some embodiments, the current source 310 sets the quiescent current (e.g., when there is no load). The bias circuit 300 as shown has a benefit of an open-loop configuration, providing wide bandwidth without stability concerns.

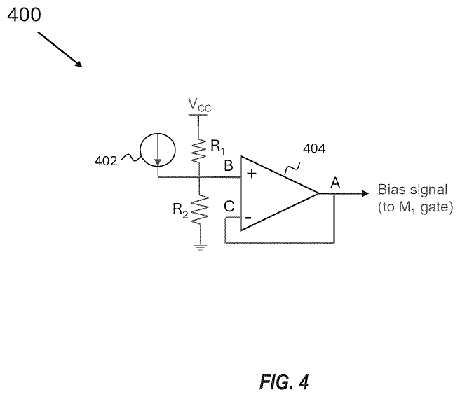

FIG. 4 illustrates another example of a bias circuit 400, in accordance with one or more embodiments of the present disclosure. In this embodiment, the bias circuit 400 includes a DC current source 402, a resistor network that includes resistors R1 and R2, and a differential amplifier 404. The differential amplifier 404 is configured in a closed-loop configuration in which the output A is fed back to one of the inputs C (that may also be known as the inverting input). The configuration of differential amplifier 404 may also be referred to as a voltage follower circuit. A bias signal is generated at output A and labeled as “Bias signal (to M₁ gate),” referring to FET M₁ in FIG. 2. In some applications, the differential amplifier 404 is a class AB unity gain buffer. The DC current source 402 may generate a DC offset current that is programmable. The resistor network R₁, R₂ may set the fraction of V_{CC} delivered to terminal B and current source 402 can be considered to shift the voltage at terminal B up or down as desired.

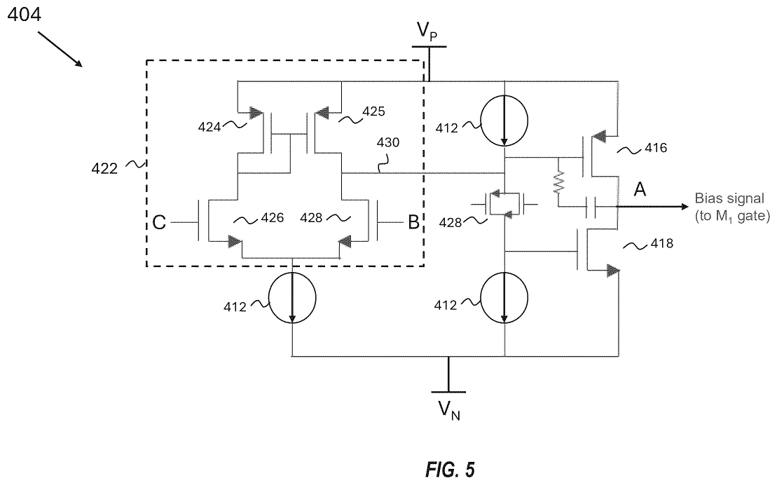

FIG. 5 illustrates an example embodiment of the differential amplifier 404 of the bias circuit 400, in accordance with one or more embodiments of the present disclosure. The differential amplifier 404 in FIG. 5 includes a first amplifier stage 422 that includes a differential pair of FETs 426, 428 and two FETs forming an active current mirror 424, 425. The first amplifier stage 422 produces a single-ended output 430. The differential amplifier 404 further includes a second amplifier stage that includes a push-pull output amplifier having push-pull FETs 416 (push) and 418 (pull). The differential amplifier 404 further includes three DC current sources, each labeled as 412. The DC current sources 412 are used to set the final stage quiescent current (e.g., when there is no load). Furthermore, each of the FETs shown in FIG. 5 (e.g., FETs 416, 418, 424, 425, 426, and 428) may be implemented as SOI/LDMOS devices. The differential amplifier 404 in FIG. 5 may be connected to voltage rails V_{P} and V_{N} as shown. In some embodiments, V_{P} may be referred to as a positive rail, and set to a variable voltage supply signal, such as V_{CC.} In some embodiments, V_{N} may be referred to as a negative rail and set to a ground voltage. The differential amplifier 404 in FIG. 5 includes a level shifter 428 (sometimes called a voltage source), which passes an AC signal from the first-stage single-ended output 430 to the NMOS pull device 418 so that it follows AC signal on gate of the push device 416, but at a different DC voltage level to set the the quiescent current Iq of output stage.

The embodiment in FIG. 5 provides a number of benefits, including providing a class AB output stage yielding good large signal behavior with lower current; feedback that can correct for nonlinear loading; and creating improved VCC look-up table (LUT) characteristics across envelope tracking (ET) operating modes. For example, in the case of ISO gain: smoother ISOgain look-up table curves. As one with skill in the art may appreciate: a uniform relationship between Pin and Vcc in the ET system is ideal and simplifies the V_{CC} look-up table. The same is generally true for other ET operating modes such as peak efficiency and/or constant compression.

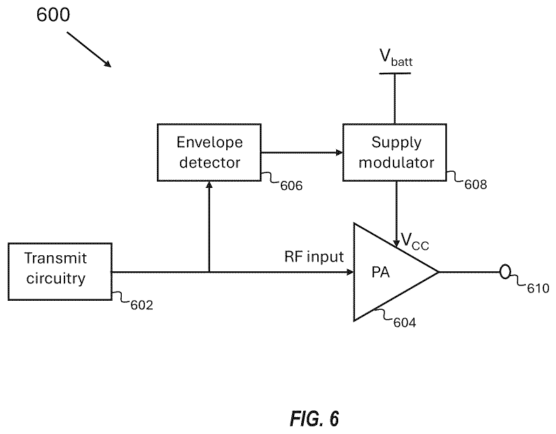

FIG. 6 illustrates an architecture of a wireless communication device 600, in accordance with one or more embodiments of the present disclosure. In this embodiment, the wireless communication device may include transmit circuitry 602 that includes conventional circuitry to convert digital data to an RF signal, such as baseband circuitry for modulating the digital data onto a baseband signal followed by RF circuitry that converts the baseband signal to an RF signal. The transmit circuitry 602 is well-known in wireless communications, and may be used to generate signals compatible with 2G, 3G, 4G, or 5G cellular communications, as examples. Other forms of wireless communications may be used, such as WiFi and satellite communications. The wireless communication device 600 further includes an envelope detector 606 and a supply modulator 608. In some embodiments, the envelope detector 606 determines a voltage supply value based on a measured envelope of the input RF signal. The wireless communication device 600 may further include a supply modulator 608 that generates a variable voltage supply signal from a stable DC voltage supply, such as a battery that produces a DC voltage output labeled as V_{batt}. The envelope detector 606 controls the voltage produced by the supply modulator 608. For example, the envelope detector 606 may employ a lookup table (LUT) in some embodiments that maps an envelope value to a desired value of V_{CC}, and the desired value of V_{CC} may be indicated to the supply modulator 608. More generally, the envelope detector 606 and the supply modulator 608 may work in conjunction to set the value of V_{CC} (a variable voltage supply signal for the PA 604).

The wireless communication device 600 may further include power amplifier (PA) 604. The PA 604 may be configured to receive an RF input signal and amplify the RF input signal to produce an output at output terminal 610. The PA 604 may be configured as power amplifier 100 in FIG. 1, with driver stage 102 being implemented using driver stage 200 in FIG. 2. The bias circuit 202 in FIG. 2 may further be implemented as bias circuit 300 in FIG. 3 or bias circuit 400 in FIG. 4. The driver stage 102 may use SOI/LDMOS devices, and the power stage (or power amplifier stage) 104 use GaAs HBT devices. As explained herein, the driver stage 102 includes a bias circuit and a cascode amplifier stage, such that the bias circuit produces a bias signal that tracks the variable voltage supply signal V_{CC}, leading to satisfactory gain dispersion, even when RF input signal bandwidth exceeds 100 MHz. The wireless communication device 600 may further include one or more antennas (not shown) for transmitting the output from output terminal 610.

The PA 604 configured using the techniques described herein may have a desirable gain dispersion. For example, the PA 604 may have a gain dispersion of 4 dB or less where gain is measured at V_{CC}=5V and V_{CC}=1V and gain data is taken for an RF output of 10 dBm (decibels expressed on a logarithmic relative to 1 milliwatt (mW) as 0 dBm).

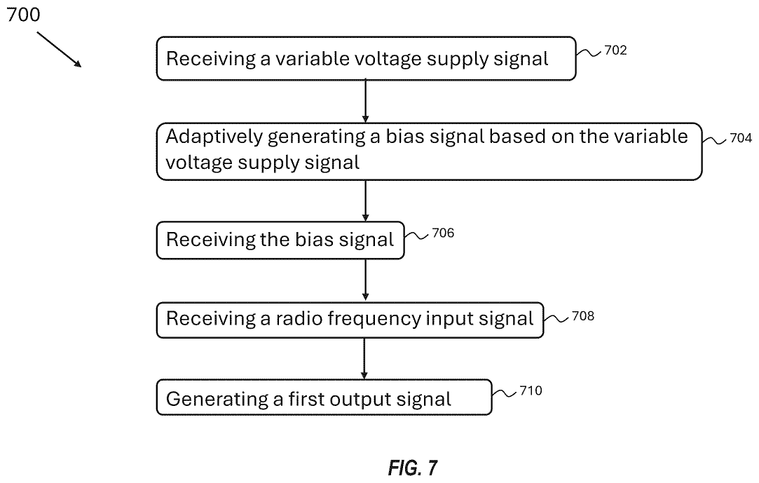

FIG. 7 is a method 700 of operating a wireless communication device, in accordance with one or more embodiments of the present disclosure. An example of such a wireless communication device to which the method 700 applies is wireless communication device 600, wherein the PA 604 includes a driver stage (such as driver stage 200) having a cascode gate bias circuit (such as bias circuit 202) that provides a bias voltage signal to a cascode amplifier circuit (such as amplifier circuit 204). In step 702, a variable voltage supply signal V_{CC} is received, e.g., by a cascode gate bias circuit 202. In step 704, a bias signal is adaptively generated based on the variable voltage supply signal to lower a gain dispersion of the power amplifier, such as PA 604. In step 706, the bias signal generated in step 704 is received by a cascode amplifier circuit, and in step 708, an RF input signal is also received by the cascode amplifier circuit. Applying steps 706 and 708 to the circuit 200 in FIG. 2, FET M₁ receives the bias signal, and FET M₂ receives the RF input signal. In step 710, an output signal is generated by the cascode amplifier circuit, such as at the drain of FET M₁ in FIG. 2. In some embodiments, the driver stage referenced with respect to method 700 includes SOI/LDMOS devices. The method 700 may further include receiving, by a power amplifier stage following the driver stage, the output signal, and amplifying, by the power amplifier stage, the output signal to generate a signal for transmission.

Further aspects of the present disclosure include the following:

Aspect 1 includes a RF circuit comprising: a driver stage configured to receive a variable voltage supply signal, the driver stage comprising: a cascode gate bias circuit configured to receive the variable voltage supply signal; and a cascode amplifier stage comprising a first FET and a second FET in a stacked configuration, wherein the cascode gate bias circuit is configured to adaptively convert the variable voltage supply signal into a bias signal for a gate of the first FET, and wherein the cascode amplifier stage is configured to receive a radio frequency input signal at a gate of the second FET and to produce an intermediate output at a drain of the first FET.

Aspect 2 includes the RF circuit of aspect 1, wherein the cascode gate bias circuit comprises: a voltage follower circuit comprising: a first amplifier stage comprising a differential pair having a single-ended output, wherein the first amplifier stage is configured to receive the bias signal via feedback; and a second amplifier stage following the first amplifier stage and configured to receive the single-ended output, wherein the second amplifier stage comprises a push-pull output amplifier, and wherein the second amplifier stage is configured to produce the bias signal.

Aspect 3 includes The RF circuit of aspect 2, wherein the driver stage further comprises a programmable DC current source and a resistor network, wherein the resistor network is configured to: receive the variable voltage supply signal and a current from the DC current source, and produce a first signal, and wherein the first amplifier stage is further configured to receive the first signal.

Aspect 4 includes the RF circuit of aspect 3, further comprising: a power amplifier stage following the driver stage, wherein the power amplifier stage is configured to generate an amplified signal based on the intermediate output.

Aspect 5 includes the RF circuit of aspect 4, wherein the first amplifier stage comprises four FETs, wherein the second amplifier stage comprises two FETs, and wherein the FETs of the voltage follower circuit and the cascode amplifier stage are SOI/LDMOS devices, and wherein the power amplifier stage comprises GaAs HBT devices.

Aspect 6 includes the RF circuit of aspect 5, wherein a gain dispersion of the driver stage is less than 3 decibels for the radio frequency input signal having a bandwidth of greater than 80 megahertz.

Aspect 7 includes the RF circuit of aspect 1, wherein the variable voltage supply signal is based on an envelope of the radio frequency input signal.

Aspect 8 includes the RF circuit of aspect 1, wherein the cascode gate bias circuit is configured in an open-loop configuration comprising: a push-pull buffer stage comprising a pull-up FET, a pull-down FET, a first direct current (DC) voltage source, and a second DC voltage source, wherein the first DC voltage source is connected to a drain of the pull-up FET, wherein the second DC voltage source is connected to a drain of the pull-down FET, and wherein the bias signal is generated between the pull-up FET and the pull-down FET.

Aspect 9 includes the RF circuit of aspect 8, wherein the cascode gate bias circuit further comprises: a second buffer stage comprising connections to each of the gates of the pull-up FET and the pull-down FET, and wherein the second buffer stage is configured to receive the variable voltage supply signal.

Aspect 10 includes a wireless communication device comprising: a power amplifier comprising: a driver stage configured to receive a variable voltage supply signal, the driver stage comprising: a cascode gate bias circuit configured to receive a first signal that is based on the variable voltage supply signal; and a cascode amplifier stage comprising a first FET and a second FET in a stacked configuration, wherein the cascode gate bias circuit is further configured to adaptively convert the first signal into a bias signal for a gate of the first FET, and wherein the cascode amplifier stage is configured to receive a radio frequency input signal at a gate of the second FET and to produce an intermediate output at a drain of the first FET; and a power amplifier stage following the driver stage, wherein the power amplifier stage is configured to generate an amplified signal based on the intermediate output.

Aspect 11 includes the wireless communication device of aspect 10, further comprising: an envelope detector configured to receive the radio frequency input signal and generate a voltage supply value based on an envelope of the radio frequency input signal; and a supply modulator configured to receive the voltage supply value and generate the variable voltage supply signal.

Aspect 12 includes the wireless communication device of aspect 11, wherein the cascode gate bias circuit comprises: a voltage follower circuit comprising: a first amplifier stage comprising a differential pair with a single-ended output; and a second amplifier stage following the first amplifier stage and configured to receive the single-ended output, wherein the second amplifier stage comprises a push-pull output amplifier, wherein the second amplifier stage is configured to produce the bias signal.

Aspect 13 includes the wireless communication device of aspect 12, wherein the driver stage further comprises a programmable DC current source and a resistor network, wherein the resistor network is configured to: receive the variable voltage supply signal and a current from the DC current source, and produce the first signal.

Aspect 14 includes the wireless communication device of aspect 13, wherein the first amplifier stage comprises four FETs, wherein the second amplifier stage comprises two FETs, and wherein the FETs of the voltage follower circuit and the cascode amplifier stage are SOI/LDMOS devices, and wherein the power amplifier stage comprises GaAs HBT devices.

Aspect 15 includes the wireless communication device of aspect 10, wherein the cascode gate bias circuit is configured in an open-loop configuration comprising: a push-pull buffer stage comprising a pull-up FET, a pull-down FET, a first direct current (DC) voltage source, and a second DC voltage source, wherein the first DC voltage source is connected to a drain of the pull-up FET, wherein the second DC voltage source is connected to a drain of the pull-down FET, and wherein the bias signal is generated between the pull-up FET and the pull-down FET.

Aspect 16 includes the wireless communication device of aspect 15, wherein the cascode gate bias circuit further comprises: a second buffer stage comprising connections to each of the gates of the pull-up FET and the pull-down FET, and wherein the second buffer stage is configured to receive the variable voltage supply signal.

Aspect 17 includes the wireless communication device of claim 10, wherein the driver stage comprises SOI/LDMOS devices, and wherein the power amplifier stage comprises GaAs HBT devices.

Aspect 18 includes a method of operating a wireless communication device, wherein the wireless communication device comprises: a driver stage, the driver stage comprising: a cascode gate bias circuit; and a cascode amplifier stage comprising a first FET and a second FET in a stacked configuration, wherein the method comprises: receiving, by the cascode gate bias circuit, a variable voltage supply signal; adaptively generating, by the cascode gate bias circuit, a bias signal based on the variable voltage supply signal to lower a gain dispersion of a power amplifier comprising the driver stage and a power amplifier stage; receiving, at gate of the first FET, the bias signal; receiving, at the gate of the second FET, a radio frequency input signal; and generating a first output signal at a drain of the first FET.

Aspect 19 includes the method of aspect 18, wherein the wireless communication device further comprises the power amplifier stage following the driver stage, and wherein the method further comprises: receiving, by the power amplifier stage, the first output signal; and amplifying, by the power amplifier stage, the first output signal to generate a signal for transmission.

Aspect 20 includes the method of aspect 19, wherein the driver stage comprises SOI/LDMOS devices, and wherein the power amplifier stage comprises GaAs HBT devices.

### Programmable Embodiments

Some or all aspects of the disclosure, may be implemented in hardware or software, or a combination of both (e.g., programmable logic arrays). Unless otherwise specified, the algorithms included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code may be applied to input data to perform the functions described in this disclosure and generate output information. The output information may be applied to one or more output devices in known fashion.

Each such computer program may be implemented in any desired computer language (including machine, assembly, or high-level procedural, logical, or object-oriented programming languages) to communicate with a computer system, and may be implemented in a distributed manner in which different parts of the computation specified by the software are performed by different computers or processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently or permanently), the storage media or device being readable by a general or special purpose programmable computer or processor for configuring and operating the computer or processor when the storage media or device is read by the computer or processor to perform the procedures described above. The inventive system may also be considered to be implemented as a non-transitory computer-readable storage medium, configured with a computer program, where the storage medium so configured causes a computer or processor to operate in a specific or predefined manner to perform the functions described in this disclosure.

### Fabrication Technologies & Options

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor”includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A radio frequency (RF) circuit comprising:
a driver stage configured to receive a variable voltage supply signal, the driver stage comprising:
a cascode gate bias circuit configured to receive the variable voltage supply signal; and
a cascode amplifier stage comprising a first field effect transistor (FET) and a second FET in a stacked configuration,
wherein the cascode gate bias circuit is configured to adaptively convert the variable voltage supply signal into a bias signal for a gate of the first FET, and wherein the cascode amplifier stage is configured to receive a radio frequency input signal at a gate of the second FET and to produce an intermediate output at a drain of the first FET.

2. The RF circuit of claim 1, wherein the cascode gate bias circuit comprises:
a voltage follower circuit comprising:
a first amplifier stage comprising a differential pair having a single-ended output, wherein the first amplifier stage is configured to receive the bias signal via feedback; and
a second amplifier stage following the first amplifier stage and configured to receive the single-ended output, wherein the second amplifier stage comprises a push-pull output amplifier, and wherein the second amplifier stage is configured to produce the bias signal.

3. The RF circuit of claim 2, wherein the driver stage further comprises a programmable direct current (DC) current source and a resistor network, wherein the resistor network is configured to:
receive the variable voltage supply signal and a current from the DC current source, and
produce a first signal, and
wherein the first amplifier stage is further configured to receive the first signal.

4. The RF circuit of claim 3, further comprising:
a power amplifier stage following the driver stage, wherein the power amplifier stage is configured to generate an amplified signal based on the intermediate output.

5. The RF circuit of claim 4, wherein the first amplifier stage comprises four FETs, wherein the second amplifier stage comprises two FETs, and wherein the FETs of the voltage follower circuit and the cascode amplifier stage are silicon-on-insulator laterally double-diffused metal oxide semiconductor (SOI/LDMOS) devices, and wherein the power amplifier stage comprises gallium arsenide heterojunction bipolar transistor (GaAs HBT) devices.

6. The RF circuit of claim 5, wherein a gain dispersion of the driver stage is less than 3 decibels for the radio frequency input signal having a bandwidth of greater than 80 megahertz.

7. The RF circuit of claim 1, wherein the variable voltage supply signal is based on an envelope of the radio frequency input signal.

8. The RF circuit of claim 1, wherein the cascode gate bias circuit is configured in an open-loop configuration comprising:
a push-pull buffer stage comprising a pull-up FET, a pull-down FET, a first direct current (DC) voltage source, and a second DC voltage source,
wherein the first DC voltage source is connected to a drain of the pull-up FET,
wherein the second DC voltage source is connected to a drain of the pull-down FET, and
wherein the bias signal is generated between the pull-up FET and the pull-down FET.

9. The RF circuit of claim 8, wherein the cascode gate bias circuit further comprises:
a second buffer stage comprising connections to each of the gates of the pull-up FET and the pull-down FET, and wherein the second buffer stage is configured to receive the variable voltage supply signal.

10. A wireless communication device comprising:
a power amplifier comprising:
a driver stage configured to receive a variable voltage supply signal, the driver stage comprising:
a cascode gate bias circuit configured to receive a first signal that is based on the variable voltage supply signal; and
a cascode amplifier stage comprising a first field effect transistor (FET) and a second FET in a stacked configuration,
wherein the cascode gate bias circuit is further configured to adaptively convert the first signal into a bias signal for a gate of the first FET, and wherein the cascode amplifier stage is configured to receive a radio frequency input signal at a gate of the second FET and to produce an intermediate output at a drain of the first FET; and
a power amplifier stage following the driver stage, wherein the power amplifier stage is configured to generate an amplified signal based on the intermediate output.

11. The wireless communication device of claim 10, further comprising:
an envelope detector configured to receive the radio frequency input signal and generate a voltage supply value based on an envelope of the radio frequency input signal; and
a supply modulator configured to receive the voltage supply value and generate the variable voltage supply signal.

12. The wireless communication device of claim 11, wherein the cascode gate bias circuit comprises:
a voltage follower circuit comprising:
a first amplifier stage comprising a differential pair with a single-ended output; and
a second amplifier stage following the first amplifier stage and configured to receive the single-ended output, wherein the second amplifier stage comprises a push-pull output amplifier, wherein the second amplifier stage is configured to produce the bias signal.

13. The wireless communication device of claim 12, wherein the driver stage further comprises a programmable direct current (DC) current source and a resistor network, wherein the resistor network is configured to:
receive the variable voltage supply signal and a current from the DC current source, and
produce the first signal.

14. The wireless communication device of claim 13, wherein the first amplifier stage comprises four FETs, wherein the second amplifier stage comprises two FETs, and wherein the FETs of the voltage follower circuit and the cascode amplifier stage are silicon-on-insulator laterally double-diffused metal oxide semiconductor (SOI/LDMOS) devices, and wherein the power amplifier stage comprises gallium arsenide heterojunction bipolar transistor (GaAs HBT) devices.

15. The wireless communication device of claim 10, wherein the cascode gate bias circuit is configured in an open-loop configuration comprising:
a push-pull buffer stage comprising a pull-up FET, a pull-down FET, a first direct current (DC) voltage source, and a second DC voltage source,
wherein the first DC voltage source is connected to a drain of the pull-up FET,
wherein the second DC voltage source is connected to a drain of the pull-down FET, and
wherein the bias signal is generated between the pull-up FET and the pull-down FET.

16. The wireless communication device of claim 15, wherein the cascode gate bias circuit further comprises:
a second buffer stage comprising connections to each of the gates of the pull-up FET and the pull-down FET, and wherein the second buffer stage is configured to receive the variable voltage supply signal.

17. The wireless communication device of claim 10, wherein the driver stage comprises silicon-on-insulator laterally double-diffused metal oxide semiconductor (SOI/LDMOS) devices, and wherein the power amplifier stage comprises gallium arsenide heterojunction bipolar transistor (GaAs HBT) devices.

18. A method of operating a wireless communication device, wherein the wireless communication device comprises:
a driver stage, the driver stage comprising:
a cascode gate bias circuit; and
a cascode amplifier stage comprising a first field effect transistor (FET) and a second FET in a stacked configuration,
wherein the method comprises:
receiving, by the cascode gate bias circuit, a variable voltage supply signal;
adaptively generating, by the cascode gate bias circuit, a bias signal based on the variable voltage supply signal to lower a gain dispersion of a power amplifier comprising the driver stage and a power amplifier stage;
receiving, at gate of the first FET, the bias signal;
receiving, at the gate of the second FET, a radio frequency input signal; and
generating a first output signal at a drain of the first FET.

19. The method of claim 18, wherein the wireless communication device further comprises the power amplifier stage following the driver stage, and wherein the method further comprises:
receiving, by the power amplifier stage, the first output signal; and
amplifying, by the power amplifier stage, the first output signal to generate a signal for transmission.

20. The method of claim 19, wherein the driver stage comprises silicon-on-insulator laterally double-diffused metal oxide semiconductor (SOI/LDMOS) devices, and wherein the power amplifier stage comprises gallium arsenide heterojunction bipolar transistor (GaAs HBT) devices.
